(19) United States
(12) Patent Application Publication
(10) Pub. No.: US 2010/0289117 A1
(43) Pub. Date: Nov. 18, 2010

(54) SHALLOW TRENCH ISOLATION STRUCTURE INCLUDING SECOND LINER COVERING CORNER OF TRENCH AND FIRST LINER

(75) Inventor: Chung-Chih Chen, Taipei City (TW)

Correspondence Address: J C PATENTS, 4 VENTURE, SUITE 250, IRVINE, CA, 92618, US

(73) Assignee: United Microelectronics Corp., Hsinchu (TW)

(21) Appl. No.: 12/844,088

(22) Filed: Jul. 27, 2010

Related U.S. Application Data
(62) Division of application No. 12/017,639, filed on Jan. 22, 2008.

(51) Int. Cl. H01L 29/06

(52) U.S. Cl. 257/510; 257/E29.02

(57) ABSTRACT

A STI structure disposed in a trench of a substrate is provided. The STI structure includes a first liner, a second liner and an insulation layer. The first liner is disposed on sidewalls of the trench, and a top of the first liner is lower than a surface of the substrate. The second liner covers the trench and the first liner. The second liner and the first liner may constitute with different materials. The insulation layer is disposed on the second liner to fill up the trench.

### CROSS-REFERENCE TO RELATED APPLICATION

This application is a divisional application of and claims priority benefit of an application Ser. No. 12/017,639, filed on Jan. 22, 2008, now pending. The entirety of each of the above-mentioned patent applications is hereby incorporated by reference herein and made a part of this specification.

### BACKGROUND OF THE INVENTION

1. Field of Invention

The present invention relates to an isolation structure and a method of fabricating the same. More particularly, the present invention relates to a shallow trench isolation (STI) structure and a method of fabricating the same.

2. Description of Related Art

Device dimensions are getting smaller and entering a field of deep submicron or less in accordance with the development of semiconductor technology. To prevent a short current from occurring between adjacent devices, an isolation structure between devices becomes very important. A frequently used method in forming an isolation structure is the shallow trench isolation (STI) process. The isolation region formed from the above technique has the advantage of scalable dimension, and a bird's beak encroachment caused by a traditional technique of local oxidation of silicon (LOCOS) can be avoided. Therefore, the shallow trench isolation structure is a better technique for the current metal-oxide-semiconductor (MOS) process.

FIG. 1 schematically illustrates a cross-sectional view of a conventional shallow trench isolation structure. Referring to FIG. 1, a pad oxide layer (not illustrated) and a mask layer (not illustrated) are sequentially formed on a substrate 100. Then, the mask layer and the pad oxide layer are patterned and a trench 108 is formed in the substrate 100. After that, an insulation layer 110 fills up the trench 108. Next, the mask layer and the pad oxide layer are removed to form a shallow trench isolation structure 112. However, during the process of removing the pad oxide layer or during each subsequent process, due to the materials of the pad oxide layer and the insulation layer 110 are both silicon oxide, the etchant of hydrofluoric acid used for the wet etching process also damages the insulation layer 110 near the corner 114 of the trench 108, resulting in the exposure of the corner 114 and the generation of the divot 116. In addition, after forming the shallow trench isolation structure 112, the etchant of hydrofluoric acid and phosphoric acid used for the subsequent cleaning process steps also generate divots or induce more serious damages. Thus, the shallow trench isolation structure formed from the conventional method generates the leakage current easily; hence, a short current between devices is resulted. Furthermore, the charges are accumulated in the divot 116 and the sub-threshold leakage current of the device is generated. Eventually, the kink effect or the gate induced drain leakage (GIDL) effect is generated, and the reliability and the yield of the device are reduced.

### SUMMARY OF THE INVENTION

The present invention provides a method of fabricating a STI structure to prevent the divot from forming near the corner of the STI structure and to avoid the leakage current of the device.

The present invention also provides a STI structure with effective isolation to prevent the short current from occurring between devices.

The present invention provides a STI structure disposed in a trench of a substrate. The STI structure includes a first liner, a second liner and an insulation layer. The first liner is disposed on sidewalls of the trench, and a top of the first liner is lower than a surface of the substrate. The second liner covers the trench and the first liner. The second liner and the first liner may constitute with different materials. The insulation layer is disposed on the second liner to fill up the trench.

According to an embodiment of the present invention, the second liner and the insulation layer may constitute with different materials.

According to an embodiment of the present invention, a material of the first liner may include silicon oxide.

According to an embodiment of the present invention, a material of the second liner may include silicon carbonitride (SiCN), silicon carbon oxide (SiCO), silicon carbide (SiC), silicon carbon oxynitride (SiCON), silicon oxynitride (SiON) or a high dielectric constant dielectric material having a dielectric constant greater than 4.

According to an embodiment of the present invention, the second liner covers a bottom of the trench.

According to an embodiment of the present invention, corners of the trench are exposed by the first liner.

According to an embodiment of the present invention, the second liner directly contacts and covers corners of the trench and an entire surface of the first liner in the trench.

According to an embodiment of the present invention, the first liner is only disposed on sidewalls of the trench.

The second liner formed at the corners of the trench according to the present invention can protect the corners of the shallow trench isolation structure from being damaged by the etchant or cleaning solution, and thus avoid the generation of the divot in the corners of the STI structure. Therefore, in accordance to the present invention, the isolation capability is effectively enhanced and the leakage current is obviated. Further, based on the present invention, the short current is prevented from occurring between devices and the reliability and the yield of the device are improved.

In order to make the aforementioned and other objects, features and advantages of the present invention comprehensible, a preferred embodiment accompanied with figures is described in detail below.

### BRIEF DESCRIPTION OF THE DRAWINGS

FIG. 1 schematically illustrates a cross-sectional view of a conventional shallow trench isolation structure.

FIGS. 2A-2E are schematic cross-sectional views illustrating a process flow of fabricating a shallow trench isolation structure according to an embodiment of this invention.

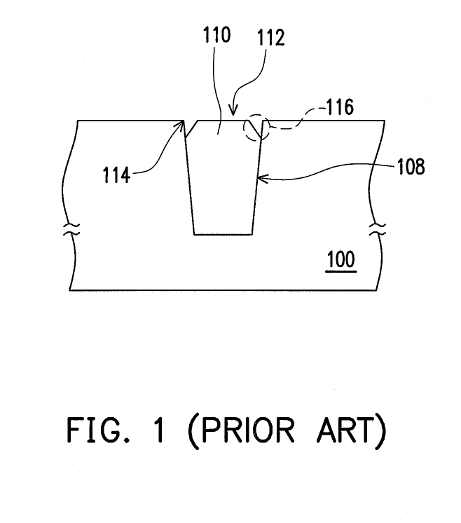

### DESCRIPTION OF EMBODIMENTS

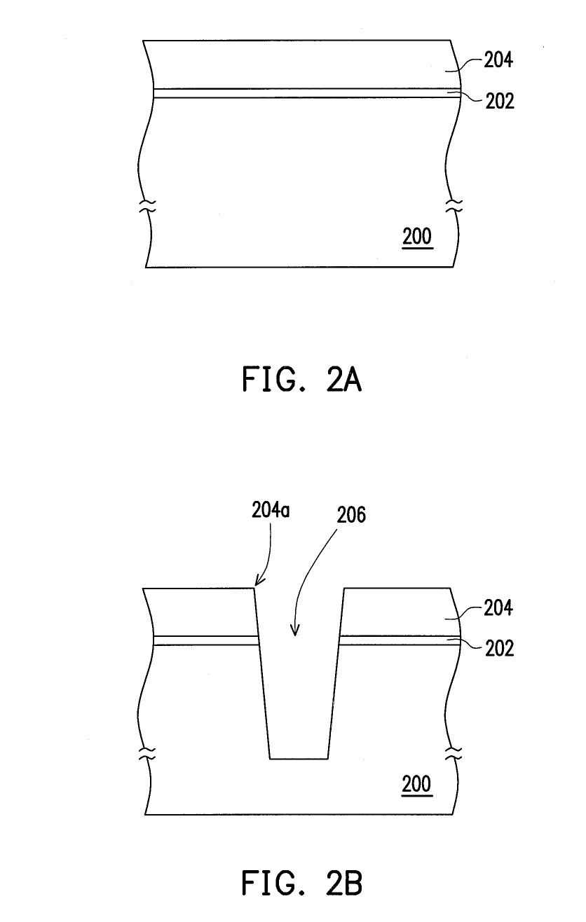

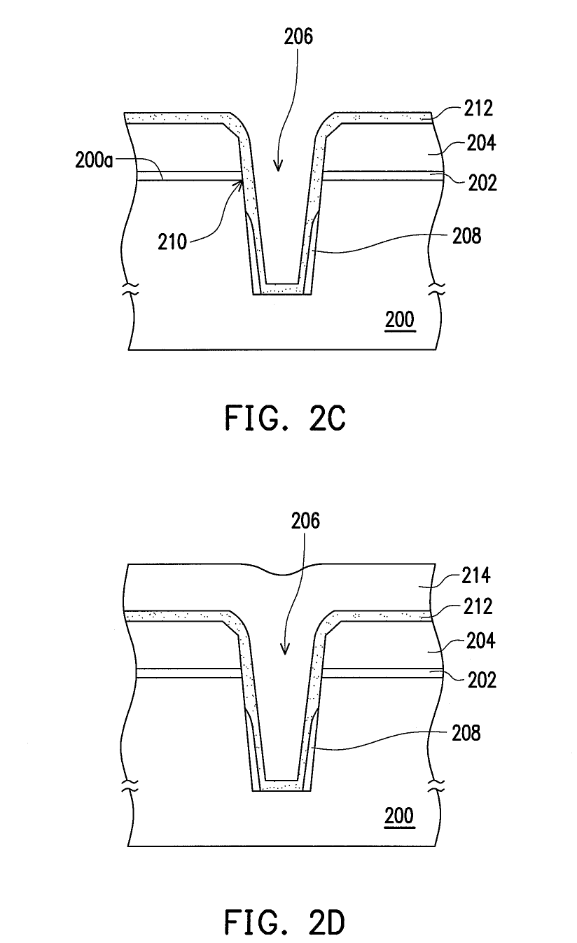

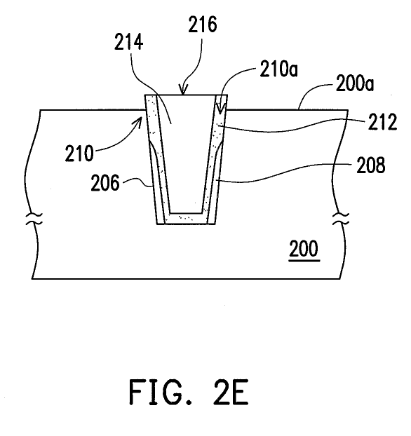

FIGS. 2A-2E are schematic cross-sectional views illustrating a process flow of fabricating a shallow trench isolation structure according to an embodiment of this invention.

Referring first to FIG. 2A, a pad oxide layer 202 and a mask layer 204 are sequentially formed on a substrate 200. The substrate 200 may be P-doped silicon, N-doped silicon, epitaxial silicon (epi-Si), gallium arsenide (GaAs), indium phosphide (InP) or germanium silicon (GeSi). The material of the pad oxide layer 202 is silicon oxide, for example. The method of forming the pad oxide layer 202 is, for example, a thermal oxidation process or a chemical vapor deposition (CVD) process. The material of the mask layer 204 is silicon nitride, for example. The method of forming the mask layer 204 is, for example, a CVD process.

Referring to FIG. 2B, the pad oxide layer 202 and the mask layer 204 are patterned and then a trench 206 is formed in the substrate 200. In one embodiment, a photolithography-and-etching process is performed to form the patterned mask layer 204. The pad oxide layer 202 and a portion of the substrate 200 are etched, using the patterned mask layer 204 as an etching mask, to form a trench 206.

Referring to FIG. 2C, a first liner 208 is formed in the trench 206. The material of the first liner 208 is silicon oxide, for example. The method of forming the first liner 208 is, for example, a thermal oxidation process. A portion of the first liner 208 is then removed so that the top of the first liner 208 is lower than the surface 200a of the substrate 200; thus, the corner 210 of the trench 206 is exposed. The removing process includes anisotropic etching, such as a dry etching process. In this embodiment, the removing process of the first liner 208 not only exposes the corner 210 of the trench 206 but also exposes the bottom of the trench 206. Furthermore, in this process step, the corner 204a of the mask layer 204 is possibly removed as shown in FIG. 2C, which is beneficial to the subsequent process for filling the trench 206.

Thereafter, a second liner 212 is formed over the substrate 200, covering the corner 210 of the trench 206 and the first liner 208. The material of the second liner 212 is a dielectric material different from the materials of the first liner 208, the pad oxide layer 202 and the mask layer 204. The material of the second liner 212 is silicon carbonitride (SiCN), silicon carbon oxide (SiCO), silicon carbide (SiC), silicon carbon oxynitride (SiCON), silicon oxynitride (SiON) or a high dielectric constant dielectric material having a dielectric constant greater than 4, such as Ta₂O₅, HfSiO₂, HfSiON, etc., for example. The method of forming the second liner 212 is, for example, an atomic layer deposition (ALD) process or a CVD process.

Referring to FIG. 2D, an insulation layer 214 is formed over the substrate 200 to fill up the trench 206. The material of the insulation layer 214 is different from that of the second liner 212. The material of the insulation layer 214 is silicon oxide, for example. The method of forming the insulation layer 214 is, for example, a PECVD process, an APCVD process, a HDPCVD process, or a sub-atmospheric chemical vapor deposition process.

Referring to FIG. 2E, the insulation layer 214, the second liner 212, the mask layer 204 and the pad oxide layer 202 outside the trench 206 are removed. In an embodiment, a portion of the insulation layer 214 and a portion of the second liner 212 are removed, using the mask layer 204 as a removing stop layer, by a chemical mechanical polishing (CMP) process, for example. The mask layer 204 and the pad oxide layer 202 are then removed so as to form a shallow trench isolation structure 216 in the substrate 200. The method of removing the mask layer 204 includes a wet etching process using hot phosphoric acid as an etchant, for example. The method of removing the pad oxide layer 202 includes a wet etching process using fluoric acid as an etchant, for example.

In another embodiment, a portion of the insulation layer 214 is removed, using the second liner 212 above the mask layer 204 as a removing stop layer, by a CMP process, for example. Next, the second liner 212, the mask layer 204 and the pad oxide layer 202 outside the trench 206 are removed. The method of removing the second liner 212 is a dry etching process or a wet etching process, for example. The method of removing the mask layer 204 and the pad oxide layer 202 is aforementioned. The unnecessary details are not given.

The corner 210 of the trench 206 is covered by the second liner 212 in the shallow trench isolation structure 216. The material of the second liner 212 is different from the materials of the mask layer 204 and the pad oxide layer 202, and the second liner 212 has the higher etching selectivity to the etchant used for removing the mask layer 204 and the pad oxide layer 202. In other words, the etchant has the lower etching rate for the second liner 212 than the mask layer 204 and the pad oxide layer 202. Therefore, the second liner 212 can protect the shallow trench isolation structure 216 from being damaged by the etchant, and the generation of the divot in the corner 210a of the shallow trench isolation structure 216 is avoided.

In addition, after the shallow trench isolation structure 216 is formed, in order to remove the residues generated from the subsequent process steps on the surface of the substrate 200, multiple cleaning process steps may be included. The cleaning solution used in these cleaning process steps, such as fluoric acid and phosphoric acid, also has a higher selectivity to the second liner 212. Thus, the corner 210a of the shallow trench isolation structure 216 is protected by the second liner 212 so that no divot is generated.

In summary, this invention provides the second liner to cover the corners of the trench; hence, the corners of the shallow trench isolation structure is protected from being damaged by the etchant or cleaning solution during the subsequent pad oxide removing step or the following cleaning process steps, and the generation of the divot is avoided. Moreover, during the removal of a part of the first liner, the corners of the mask layer are also removed at the same time, which is beneficial for filling the trench thereafter. Therefore, the isolation capability of the STI structure is enhanced, and thus the reliability and the yield of the device are improved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A shallow trench isolation (STI) structure disposed in a trench of a substrate, comprising:
a first liner disposed on sidewalls of the trench, wherein a top of the first liner is lower than a surface of the substrate;
a second liner covering the trench and the first liner, wherein the second liner and the first liner comprise different materials; and
an insulation layer disposed on the second liner to fill up the trench.

2. The STI structure of claim 1, wherein the second liner and the insulation layer comprise different materials.

3. The STI structure of claim 1, wherein a material of the first liner comprises silicon oxide.

4. The STI structure of claim 1, wherein a material of the second liner comprises silicon carbonitride (SiCN), silicon carbon oxide (SiCO), silicon carbide (SiC), silicon carbon oxynitride (SiCON), silicon oxynitride (SiON) or a high dielectric constant dielectric material having a dielectric constant greater than 4.

5. The STI structure of claim 1, wherein the second liner covers a bottom of the trench.

6. The STI structure of claim 1, wherein corners of the trench are exposed by the first liner.

7. The STI structure of claim 6, wherein the second liner directly contacts and covers corners of the trench and an entire surface of the first liner in the trench.

8. The STI structure of claim 1, wherein the first liner is only disposed on sidewalls of the trench.
